(19) United States
(12) Patent Application Publication
(10) Pub. No.: US 2005/0208775 A1
(43) Pub. Date: Sep. 22, 2005

(54) METHOD FOR GROWING A GATE OXIDE LAYER ON A SILICON SURFACE WITH PRELIMINARY N2O ANNEAL

(76) Inventor: Shian-Jyh Lin, Chia-Yi Hsien (TW)

Correspondence Address: NORTH AMERICA INTERNATIONAL PATENT OFFICE (NAIPC), P.O. BOX 506, MERRIFIELD, VA, 22116, US

(21) Appl. No.: 10/711,178

(22) Filed: Aug. 30, 2004

(30) Foreign Application Priority Data
Mar. 17, 2004 (TW) 093107164

(51) Int. Cl. H01L 21/66; G01R 31/26; H01L 21/469; H01L 21/31

(52) U.S. Cl. 438/769

(57) ABSTRACT

The present invention relates to a method for growing a robust, high-quality gate oxide layer on a silicon surface. The resultant gate oxide layer made according to the present invention can pass the standard 50K times 14V high-voltage stress testing. The preferred embodiment of this invention includes a step of preliminary low-pressure N₂O annealing that is carried out in an air-tight chamber at a temperature of less than 1000° C., a pressure below 0.2 torr, and N₂O flow rate of below 8000 sccm. The preliminary low-pressure N₂O annealing of the silicon surface is performed prior to the growth of high-quality gate oxide layer. In another preferred embodiment, N₂O may be replaced with NO.

### BACKGROUND OF INVENTION

1. Field of the Invention

The present invention relates to a method for growing a high-quality gate oxide layer on a silicon surface, and more particularly, to a method for growing a high-quality gate oxide layer with low-pressure N₂O preliminary anneal. The gate oxide layer made according to the present invention method can sustain relatively higher voltage (up to 14V) than that made according to the prior art methods at the same thickness level.

2. Description of the Prior Art

In the formation of integrated circuits on the surface of a semiconductor substrate, a gate oxide layer is typically grown over bare surface of a mono-crystalline substrate. The formation of this layer of stoichiometric and non-stoichiometric oxide is generally well known in the art. The gate oxide layer is preferably grown by means of thermal oxidation techniques. In the formation of for instance MOSFET devices, a polysilicon layer is deposited over the gate oxide layer and patterned to form the polysilicon gate electrode of the MOSFET device. The creation of high quality gate oxide is of critical importance in the fabrication of semiconductor devices since gate oxide quality has a direct effect on device yield, reliability and performance.

Generally, in accordance with the prior art methods, the gate oxide layer is thermally grown on a bare silicon surface by means of either dry oxidation or wet oxidation techniques, followed by hydrogen (H₂) or nitrogen (N₂) annealing. For example, U.S. Pat. No. 6,204,205, entitled “Using H₂ Anneal to Improve the Electrical Characteristics of Gate Oxide”, teaches a method to anneal the gate oxide after the gate oxide has been grown. The method includes a two-step anneal. A first anneal using H₂ followed by a second anneal using N₂. In a second embodiment of this invention teaches a one-step anneal using H₂ mixed with N₂. The third embodiment of this invention teaches a one step anneal using pure H₂. According to U.S. Pat. No. 6,204,205, a thin gate oxide is grown at a temperature of 750° C. to 900° C. and to a thickness of 10 and 15 Angstrom. A H₂ or N₂ anneal process is then performed under atmospheric pressure, at a temperature between about 800° C. and 1200° C. for a duration of between about 20 and 40 seconds.

U.S. Pat. No. 6,184,110, entitled “Method of Forming Nitrogen Implanted Ultrathin Gate Oxide for Dual Gate CMOS Devices”, teaches a method of forming a nitrogen-implanted gate oxide in a semiconductor device includes preparing a silicon substrate; forming an oxide layer on the prepared substrate; and implanting N+ or N₂+ ions into the oxide layer in a plasma immersion ion implantation apparatus.

U.S. Pat. No. 6,498,365, entitled “FET Gate Oxide Layer with Graded Nitrogen Concentration”, teaches a gate oxide film made on a semiconductor substrate; and first transistors each having a first gate formed on the gate oxide film and a pair of source/drain formed in confrontation in the semiconductor substrate. The gate oxide film has a higher nitrogen concentration in its portion nearer to the first gates than that of its portion nearer to the semiconductor substrate. According to U.S. Pat. No. 6,498,365, a 60 Å thick silicon oxide layer is thermally grown on a silicon substrate. A 20 Å thick polysilicon or amorphous silicon layer is then deposited onto the silicon oxide layer. Thereafter, the polysilicon or amorphous silicon layer is transformed into nitrogen oxide layer at a temperature of 900° C., at a pressure of 400 Torr in N₂O or NO atmosphere.

In light of the above, the gate oxide layer according to the prior art methods are generally made by firstly growing a layer of oxide on a silicon surface, followed by annealing the layer of oxide in hydrogen or nitrogen atmosphere. However, the gate oxide layer of the prior arts cannot sustain high voltage operation conditions such as a high voltage of 14V or even higher.

### SUMMARY OF INVENTION

Accordingly, it is the primary object of the present invention to provide a method for making a robust, high-quality gate oxide layer that has improved electric characteristics such as superior reliability at high voltage (up to 14V) operation conditions.

According to the claimed invention, a method of growing a high-quality gate oxide layer is provided. A semiconductor substrate having thereon at least one silicon active area is prepared. The silicon active area is washed to obtain a clean silicon active area. A preliminary anneal process is then carried out. The semiconductor substrate is placed in an airtight chamber. N₂O/NO gas is introduced into the airtight chamber such that the silicon active area is in contact with the N₂O/NO gas. After performing the preliminary anneal process, a nitrogen oxide thin layer with limited nitrogen-silicon bonds is formed on the silicon active area. A gate oxide layer is grown on the nitrogen oxide thin layer.

Other objects, advantages and novel features of the invention will become more clearly and readily apparent from the following detailed description when taken in conjunction with the accompanying drawings.

### BRIEF DESCRIPTION OF DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings:

FIG. 1 is a flowchart illustrating a first preferred embodiment of the present invention;

FIG. 2 is a flowchart illustrating a second preferred embodiment of the present invention; and

FIG. 3 to FIG. 5 are schematic cross-sectional diagrams illustrating the process for making the gate oxide layer according to this invention.

### DETAILED DESCRIPTION

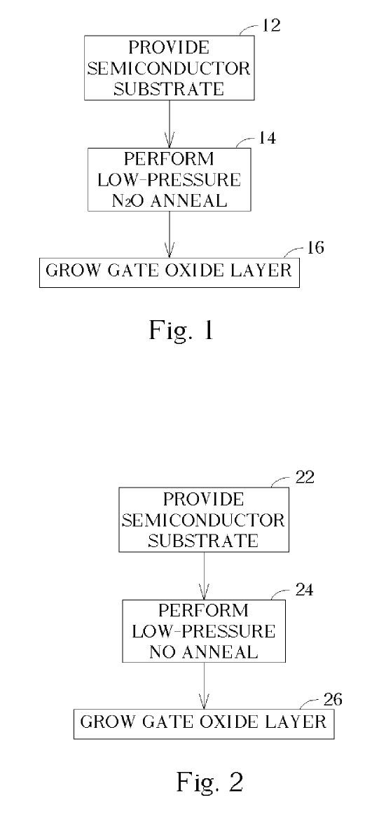

Please refer to FIG. 1. FIG. 1 is a flowchart illustrating a first preferred embodiment of the present invention. In Step 12, a semiconductor substrate such as a mono-crystalline silicon substrate is prepared. A plurality of silicon active areas that are isolated by device isolation structures are provided. Ordinarily, several cleaning procedures known in the art are carried out to obtain a clean silicon surface. After the cleaning process, a thin native oxide of few angstroms is formed on the silicon active areas. In Step 14, the semiconductor substrate is subjected to a preliminary anneal treatment. The preliminary anneal treatment is carried out in an airtight chamber. 10 sccm˜8000 sccm N₂O gas is introduced into the chamber to maintain a low pressure of below 0.2 Torr. The anneal temperature is less than 1000° C. at a ramp rate of 5° C./min to 100° C./min. In Step 16, a high-quality gate oxide film is grown on the N₂O pre-treated silicon surface (of the active areas) either by wet oxidation or by dry oxidation techniques.

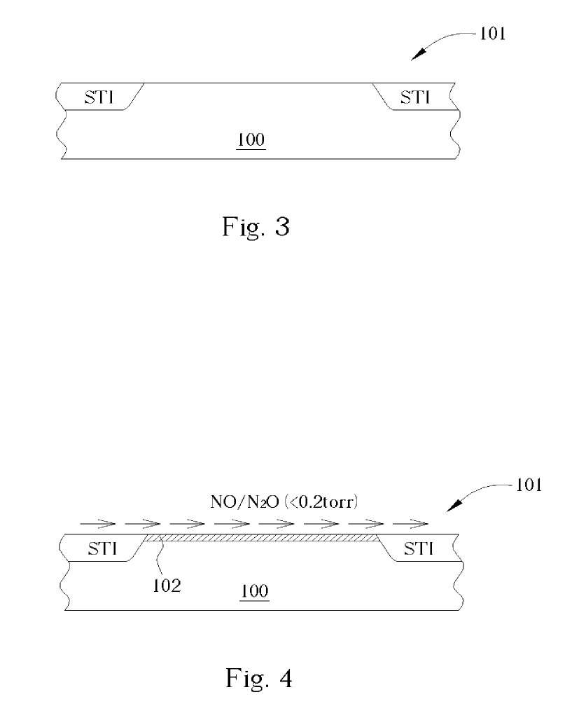

Please refer to FIG. 2. FIG. 2 is a flowchart illustrating a first preferred embodiment of the present invention. In Step 22, likewise, a semiconductor substrate such as a mono-crystalline silicon substrate is prepared. A plurality of silicon active areas that are isolated by device isolation structures are provided. Several cleaning procedures are carried out to obtain a clean silicon surface. After the cleaning process, a thin native oxide of few angstroms is formed on the silicon active areas. In Step 24, the semiconductor substrate is subjected to a preliminary anneal treatment. The preliminary anneal treatment is carried out in an airtight chamber. 10 sccm˜8000 sccm NO gas is introduced into the chamber to maintain a low pressure of below 0.2 Torr. The anneal temperature is less than 1000° C. at a ramp rate of 5° C./min to 100° C./min. The process time for the preliminary anneal treatment is less than 60 minutes. In Step 26, a high-quality gate oxide film is grown on the NO pre-treated silicon surface (of the active areas) either by wet oxidation or by dry oxidation techniques.

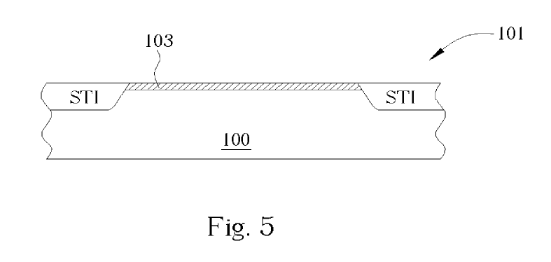

Please refer to FIG. 3 to FIG. 5. FIG. 3 to FIG. 5 are schematic cross-sectional diagrams illustrating the process for making the gate oxide layer according to this invention. As shown in FIG. 3, a semiconductor substrate 100 is prepared. The semiconductor substrate 100 contains at least one active area 101 that is isolated by STI regions. The active area 101 is cleaned by methods or recipes known in the art, for example, DHF or the like, to obtain a clean silicon surface. Naturally, a native oxide of few angstroms (not shown) is formed on the clean silicon surface of the active area 101. The semiconductor substrate 100 is subjected to a preliminary N₂O/NO anneal treatment.

As shown in FIG. 4, the semiconductor substrate 100 is transferred to an airtight reaction chamber (not shown) such as an RTP chamber or a furnace chamber. N₂O (or NO) flows into the reaction chamber at a flow rate of about 10˜8000 sccm. It is noteworthy that the pressure at this phase is kept at a low pressure of about 0.2 Torr or even lower. The anneal temperature is less than 1000° C. The semiconductor substrate 100 is annealed in the above-described conditions in 60 minutes. It is believed that nitrogen-silicon (N—Si) bonds are formed at the surface of the active area 101, thereby forming a nitrogen oxide thin layer 102 having a thickness of less than 5 angstroms. The pressure parameter is of one of the most importance because the low pressure (<0.2 torr) of the N₂O gas limits the number of nitrogen-silicon (N—Si) bonds at the surface of the active area 101, which might adversely affect the mobility of electrons in the channel region.

As shown in FIG. 5, a wet or dry oxidation process is carried out to form a high-quality gate oxide layer 103 on the pre-treated active area 101. The resultant gate oxide layer 103 made according to the present invention can pass the standard 50K times 14V high-voltage stress testing.

Those skilled in the art will readily observe that numerous modification and alterations of the present invention method may be made while retaining the teachings of the invention. Accordingly, the above disclosure should be construed as limited only by the metes and bounds of the appended claims.

1. A method of growing a gate oxide layer, comprising:
providing a semiconductor substrate having thereon at least one silicon active area;
cleaning said silicon active area to obtain a clean silicon active area;
performing a preliminary anneal process, wherein said semiconductor substrate is placed in an airtight chamber, N₂O gas is introduced into said airtight chamber such that said silicon active area is in contact with said N₂O gas, wherein after performing said preliminary anneal process, a nitrogen oxide thin layer with limited nitrogen-silicon bonds is formed on said silicon active area; and
growing a gate oxide layer on said nitrogen oxide thin layer.

2. The method of claim 1 wherein said preliminary anneal process is carried out at a low pressure of equal to or less than 0.2 Torr.

3. The method of claim 1 wherein said preliminary anneal process is carried out at a temperature of less than 1000° C.

4. The method of claim 1 wherein said N₂O gas introduced into said airtight chamber has a flow rate of about 10˜8000 sccm.

5. The method of claim 1 wherein said preliminary anneal process is carried out at aramp rate of 5° C./min to 100° C./min.

6. A method of forming a gate oxide layer, comprising:
providing a semiconductor substrate having thereon at least one active area;
cleaning said silicon active area;
performing a preliminary anneal process, wherein said semiconductor substrate is placed in an airtight chamber, NO gas is introduced into said airtight chamber such that said silicon active area is in contact with said NO gas, wherein after performing said preliminary anneal process, a nitrogen oxide thin layer with limited nitrogen-silicon bonds is formed on said silicon active area; and
growing a gate oxide layer on said nitrogen oxide thin layer.

7. The method of claim 6 wherein said preliminary anneal process is carried out at a low pressure of equal to or less than 0.2 Torr.

8. The method of claim 6 wherein said preliminary anneal process is carried out at a temperature that is less than 1000° C.

9. The method of claim 6 wherein said NO gas introduced into said airtight chamber has a flow rate of about 10˜8000 sccm.

10. The method of claim 6 wherein said preliminary anneal process is carried out at a ramp rate of 5° C./min to 100° C./min.
